(19) United States
(12) Patent Application Publication
(10) Pub. No.: US 2024/0413823 A1
(43) Pub. Date: Dec. 12, 2024

(54) ACTUATING MODULE FOR A VEHICLE AND DECORATIVE ELEMENT COMPRISING AN ACUATING MODULE

(71) Applicant: Witte Automotive GmbH, Velbert (DE)

(72) Inventors: Reinaldo MENSCH, Wuppertal (DE); Axel SCHÜTZ, Wuppertal (DE); Patrick HANDL, Dormagen (DE)

(21) Appl. No.: 18/735,284

(22) Filed: Jun. 6, 2024

(30) Foreign Application Priority Data
Jun. 6, 2023 (DE) 10 2023 205 276.8

(51) Int. Cl. H03K 17/975; G01L 1/14; H03K 17/96

(52) U.S. Cl. CPC H03K 17/975; G01L 1/142; H03K 17/962

(57) ABSTRACT

An actuating module for a vehicle may have an actuation sensor for executing a switching function and an electronic evaluation unit connected to the actuation sensor. The actuation sensor may have a first fixed sensor element with a first sensitivity region, a second fixed sensor element with a second sensitivity region and a sensor element which is movable relative to the fixed sensor elements and is arranged opposite the fixed sensor elements. When an actuating force acts on the actuation sensor, the movable sensor element can be displaced at least in some regions. A decorative element for the vehicle may have the actuating module.

### FIELD

The invention relates to an actuating module for a vehicle, comprising at least one actuation sensor for executing a switching function. Furthermore, the invention relates to a decorative element having such an actuating module.

Actuating modules in the form of handle modules are known for example on vehicle doors, tailgates, or engine hoods. These are usually provided with a handle element which can be pivoted outward in order to be able to open the vehicle door, the tailgate, or the engine hood. Handle modules can comprise electronic sensor modules for opening a lock on the door.

### BACKGROUND

The object of the present invention is to provide an actuating module that is improved with respect to the prior art and which is capable of detecting different actuations. Furthermore, the object addressed by the present invention is that of providing a decorative element having an actuating module which is compact and enables intuitive actuation.

With regard to the actuating module, and with regard to the decorative element, the object is achieved according to the invention by the features indicated in the claims described herein.

Further developments of the invention are the subject matter of the dependent claims.

An actuating module for a vehicle comprises at least an actuation sensor for executing a switching function and an electronic evaluation unit connected to the actuation sensor, wherein the actuation sensor comprises at least a plurality of sensor elements which are set up and arranged to overlap one another at least in some regions such that different actuating forces can be detected by measurement and transformed into an actuation signal or trigger signal independently of the actuation location.

Such an actuating module with a plurality of sensor elements arranged partially overlapping, in particular one above the other, makes it possible to detect actuating forces having different strengths and/or to compensate for different tolerances, in particular component tolerances and/or assembly tolerances. Through the transformation, in particular signal analysis and processing, of the different actuating forces detected by measurement into the actuation signal or trigger signal (also called actuation pulse), the actuation can also be detected regardless of location.

In particular, the different actuating forces can be processed for signaling purposes, wherein the different actuating forces are compared with one another and/or with stored threshold values and an actuating signal or trigger signal for a switching function is generated depending on the comparison.

The sensor elements can be of the same type and/or of different types, for example as a combination of fixed, in particular stationary, sensor elements and movable sensor elements and/or as a combination of field sensors and pressure sensors.

In particular, the sensor elements can detect the same physical variables, for example a changing electric field or a pressure, and/or different physical variables, in particular a changing electric field, for example a capacitive field, and a pressure, for example an actuation pressure. In other words, the actuating force can be detected in different ways and uniformly processed.

### SUMMARY

The actuating module for a vehicle according to the invention comprises at least an actuation sensor for executing a switching function and an electronic evaluation unit electrically connected to the actuation sensor, wherein the actuation sensor has at least two fixed sensor elements and a sensor element which is movable relative to the fixed sensor elements and is arranged opposite the fixed sensor elements. In particular, the actuation sensor comprises a first fixed, for example stationary, sensor element with a first sensitivity region and a second fixed, for example stationary, sensor element with a second sensitivity region, wherein the movable sensor element is arranged overlapping the fixed sensor elements and can be displaced, at least in some regions, relative to the fixed sensor elements when an actuating force acts on the actuation sensor.

The movable sensor element can be arranged at different distances from the fixed sensor elements and/or the sensitivity regions.

When an actuating force acts on the actuation sensor, the movable sensor element can be displaced, at least in some regions, in such a way that an actuation stroke resulting from the actuating force can be detected in the first sensitivity region and/or in the second sensitivity region and can be compared with at least one predetermined threshold value. The sensitivity regions can be set or settable so as to be different.

The evaluation unit can be set up to detect an actuation stroke on the basis of a displacement of the movable sensor element into the first sensitivity region and/or into the second sensitivity region and to compare this with a predefined threshold value in order to generate a trigger signal for a switching function if the threshold value is exceeded. The sensitivity regions can be the same or different. Depending on how the sensitivity regions are set, the actuation sensor can react comparatively more or less sensitively to a change in capacitance. When the movable sensor element is displaced, a distance between the movable sensor element, for example a trigger element, and at least one of the fixed sensor elements is reduced or increased so that a measuring field arranged therebetween changes. For example, the sensitivity region in each case is an adjustable detection region. The detection region can be enlarged or reduced in the longitudinal direction, transverse direction and/or vertical direction in relation to the actuation sensor. For example, a shape of the detection region, such as linear, lobe-shaped, or conical, can be set. The sensitivity region in each case can be sensitive to changes in an electric field, in particular a magnetic field, in the region around the relevant fixed sensor element either to the same or different extents. For example, sensitivity regions of the fixed sensors spanning different distances result in different distances between the movable sensor element in the rest position and an outer limit of the sensitivity regions.

Through pressing on the actuation sensor, an opening request is detected, and for example an electronic locking system is opened as a switching function. The movable sensor element can be pressed at any point relative to the two fixed sensor elements in order to trigger an actuation and generate a control signal, such as an opening signal or closing signal. This enables intuitive actuation and operation. The movable sensor element can be designed to be movable and/or flexible, in particular elastically deformable, such that minimum actuation paths of a few millimeters, for example tenths of a millimeter or greater, for example in a range from 0.5 mm to 5 mm, in particular from 1 mm to 4 mm or 1.5 mm to 3 mm, can be detected.

The advantages achieved with the invention consist in particular in the fact that such an actuating module can compensate for larger tolerances during installation, for example in a decorative element and/or in a vehicle body, as well as for the introduction of forces. By means of a query that can be carried out with the evaluation unit, the actuating module can realize largely identical actuating forces via the actuation sensor or can detect identical actuating forces and/or actuation strokes, regardless of where the force is introduced, for example on the outside of or in the center of the actuation sensor.

The movable sensor element and the fixed sensor elements are arranged relative to each other in such a way that when an actuating force acts on the actuation sensor, the movable sensor element can be displaced relative to the fixed sensor elements depending on the ratio.

For example, the measuring sensitivity of the actuation sensor can be increased by using two fixed sensor elements and one sensor element that can move relative thereto. In addition, the invention also enables the same measurement sensitivities even for vehicle elements of different sizes, such as a decorative element, an emblem, or a dashboard component. The actuating module is therefore suitable for various applications. For example, tolerances can be compensated for via the arrangement of the sensor elements of the actuation sensor and a transmission ratio when there is a plurality of sensor surfaces on the actuation sensor at the same time. The sensor surfaces extend, for example, over a surface of the movable sensor element and its arrangement relative to the fixed sensor elements.

For example, the arrangement of the sensor elements can be used to detect whether pressure is acting on the outside of the actuation sensor or in the center thereof. The evaluation unit, for example a processor arranged in the evaluation unit, is able to convert an application of force to the actuation sensor, since the specified threshold value can be stored differently via the number of measured values of each of the individual sensor elements, in particular the fixed sensor elements, for example in the form of electrodes, in order to realize a comparatively uniform actuation force overall and/or to detect different actuation forces. This means that the same actuating forces can be provided via the actuation sensor regardless of location. The actuating force results in an actuating movement or an actuation stroke of the movable sensor element. The deeper the movable sensor element penetrates, the greater the change in field can be, and the evaluation unit can draw conclusions about the actuation stroke from the size of the change in field. By setting a threshold value, for example, actuation strokes below a predeterminable or predetermined value can be recognized as insufficient for triggering a switching function. In this way, false triggering, for example due to external environmental influences, can be avoided (fail-safe). If the predefinable or predefined threshold value is found to be exceeded, an actuation stroke can be deemed sufficient to trigger a switching function.

In one embodiment, the actuation sensor is designed as a force-controlled capacitive actuation sensor. In particular, the actuating module is designed as a so-called MOC module (metal-over-cap module) in which internal metal sensor components, in particular electrodes, of the actuation sensor are outwardly encapsulated. The electronic evaluation unit is connected to the capacitive actuation sensor at least for the transmission of signals. An actuation path of the actuating element, in particular an actuation path traveled due to the pressure of the user's hand on the actuating module, can be determined by means of the electronic evaluation unit on the basis of a detected change in capacitance of the capacitive actuation sensor. This reduces or increases the distance between the movable sensor element, e.g., a trigger element, and the fixed sensor elements, so that a measuring field arranged therebetween changes. For this purpose, the movable sensor element is designed, for example, as a lever-like spring plate or a lever-like spring sheet. For example, the movable sensor element forms an electrode and the fixed sensor elements form counter-electrodes.

The evaluation unit is set up to record a measured value at the first fixed sensor element and a measured value at the second fixed sensor element when the movable sensor element is displaced, and to compare these values with each other and/or with a threshold value in each case in order to generate a trigger signal for executing a switching function.

In a development, each fixed sensor element is assigned at least one threshold value to be exceeded in order to generate a trigger signal.

In a development, when substantially the same measured values are determined at the fixed sensor elements, the evaluation unit is set up to compare these measured values with associated threshold values. If substantially identical or almost identical measured values are determined, the evaluation unit is able to recognize that a force is being applied to the actuation sensor as centrally as possible. If the predefined assigned threshold values are exceeded, the evaluation unit generates a trigger signal, for example an opening signal, wherein a door lock is unlocked and/or a door movement is initiated.

In a development, when different measured values are determined at the fixed sensor elements, the evaluation unit is set up to compare one of the measured values with an associated threshold value. If different measured values are determined, the evaluation unit is able to recognize that a force is being applied to the actuation sensor off-center. The evaluation unit can be set up to use a comparatively higher or lower measured value of the recorded measured values for further analysis and to compare it with an associated predetermined threshold value. The evaluation unit can be set up to compare the measured values of the fixed sensor elements with each other and to identify a threshold value to be used for further comparison depending on the result determined from the comparison of the measured values.

In a development, when an actuation stroke in the first sensitivity region or in the second sensitivity region is detected, the evaluation unit is set up to compare this stroke with a predefined first threshold value or a predefined second threshold value. When an actuation stroke in the first sensitivity region and in the second sensitivity region is detected, the evaluation unit is set up to compare this stroke with a predefined third threshold value. For example, the threshold values are set or settable so as to be different. For example, the actuating forces can be adjusted, in particular by setting predeterminable threshold values. The threshold values can be storable or stored in the evaluation unit.

In a development, the movable sensor element is arranged at a distance from the fixed sensor elements and overlapping them. The fixed sensor elements are arranged one behind the other or next to each other, for example. The fixed sensor elements are adjacent to each other. The fixed sensor elements are arranged at a distance from each other. At least one end stop can be arranged between the fixed sensor elements, against which stop the movable sensor element can rest in an end actuation position. The end stop can be a spacer.

In a development, the movable sensor element is designed as a lever and is resiliently arranged at a predetermined angle to the fixed sensor elements.

In a development, the movable sensor element is resiliently mounted on a printed circuit board on one side. The movable sensor element has a free lever end with at least one predetermined incline.

In a development, the movable sensor element comprises at least a first lever portion, which is arranged with a first incline at a distance from the first fixed sensor element, and a second lever portion, which is arranged with a second incline at a distance from the second fixed sensor element. The first incline and the second incline can be different or the same.

The decorative element for a vehicle according to the invention comprises at least one actuating module. The decorative element can comprise two identical actuating modules that are arranged mirror-inverted to each other. Each of the actuating modules comprises two fixed sensor elements and one movable sensor element, which can be displaced relative to the two fixed sensor elements. This allows an exact actuation location to be determined by evaluating the measured values of the fixed sensor elements. An actuation surface can also be extended or enlarged. A surface of the decorative element can deform elastically in some regions when an actuating force is applied, causing a displacement of the movable sensor element. The surface of the decorative element can be formed by a housing of the actuating module. The decorative element can be designed as a separate component, wherein the actuating module can be arranged or is arranged in a receiving space of the decorative element.

The decorative element can be an emblem, for example. The decorative element can comprise at least one integrated actuating module. The decorative element can be provided for a movable vehicle element, in particular for a sliding door, a tailgate, or an engine hood or front hood of a vehicle.

Alternatively, the actuating modules can be arranged mirror-symmetrically.

By arranging a plurality of actuating modules next to each other or behind each other, in particular adjacently to each other, a plurality of sensor surfaces can be provided, which can be used, for example, to compensate for tolerances that may result from the installation of the decorative element in a vehicle body. For example, the decorative element can terminate flush with the outer skin of a vehicle.

The advantages achieved with the invention in particular consist in the fact that such a decorative element, designed as an integrated actuating module, enables intuitive opening of the movable vehicle element, such as a flap or a cover. By pressing on the decorative element, for example an emblem on the movable vehicle element, an opening request is detected by the actuation sensor and, for example, an electronic locking system is opened as a switching function. A surface of the decorative element can act as an actuating surface and/or sensor surface that can be pressed against the movable sensor element when a force is applied. Due to the arrangement of the at least one actuating module, the decorative element can be pressed at any point in order to perform an actuation and trigger a control signal, such as an opening signal or closing signal. The decorative element itself can be designed as an actuating element. This enables intuitive actuation and operation. The decorative element is designed to be flexible, in particular elastically deformable, so that minimal actuation paths can be detected.

### DESCRIPTION OF THE FIGURES

Embodiments of the invention are explained in greater detail with reference to the drawings, in which:

FIG. 1 is a perspective view of a vehicle having a decorative element arranged on the outside with an integrated actuating module,

FIG. 2 is a schematic side view of an actuating module according to the invention with an actuation sensor and an electronic unit,

FIG. 3 is a schematic top view of a decorative element with two adjacent actuating modules, and

FIG. 4 is a schematic side view of a further embodiment of an actuating module according to the invention with an actuation sensor and an electronic unit.

### DETAILED DESCRIPTION

Parts corresponding to one another are provided with the same reference signs in all the drawings.

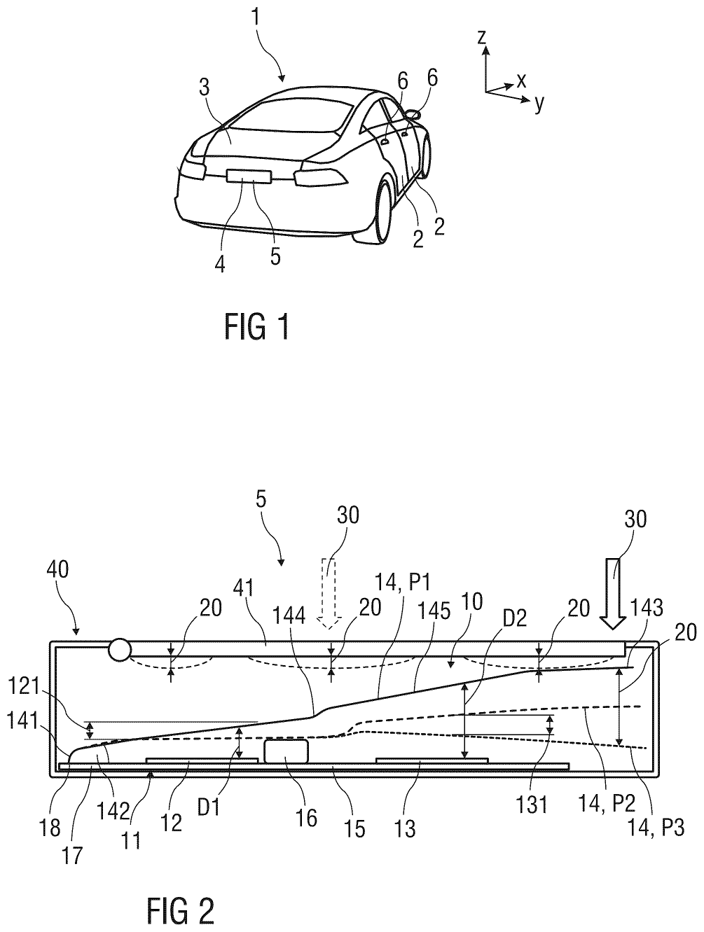

FIG. 1 is a schematic illustration of a vehicle 1. The vehicle 1 has a plurality of electronically switchable regions on its outer side. For example, the vehicle 1 has a decorative element 4, in particular an emblem, in the region of a door 2 or a tailgate 3. An actuating module 5 for an electronic locking system, in particular for unlocking, locking, opening and/or closing the electronic locking system, in particular an electronic lock, the door 2, or the tailgate 3, is integrated in the decorative element 4. In particular, the actuating module 5 is used to detect at least one manual actuation by a user's hand.

The actuating module 5 is arranged in the decorative element 4 of the door 2 or the tailgate 3, in particular on the inside of the decorative element 4.

The actuating module 5 enables the activation of a corresponding function of the vehicle 1, such as opening or closing the door 2, unlocking or locking a tailgate lock or hood lock, or opening or closing the tailgate 3, in a simple manner. For this purpose, the vehicle 1 can be equipped with a plurality of actuating modules 5. The actuating module 5 can be arranged both in the decorative element(s) 4, such as in an emblem arranged on the vehicle 1, and also in a handle 6.

FIG. 2 shows a schematic side view of an actuating module 5 according to the invention comprising an actuation sensor 10 and an electronic unit 11. The actuating module 5 is an electronic sensor module.

The actuation sensor 10 comprises at least a first fixed sensor element 12, a second fixed sensor element 13, and a sensor element 14 that is movable relative to the fixed sensor elements 12, 13.

The movable sensor element 14 is arranged at a distance from and opposite the fixed sensor elements 12, 13. The electronic unit 11 is connected to the sensor elements 12 to 14 for triggering a switching signal. The electronic unit 11 comprises, for example, a printed circuit board 15 (also referred to as a circuit board).

The fixed sensor elements 12, 13 are formed, for example, as metal layers, such as copper layers, on the printed circuit board 15. The sensor elements 12 to 14 are designed in such a way that an electric field stretches therebetween, which field is used to evaluate an actuation stroke 20. Depending on the design of the actuation sensor 10, the first fixed sensor element 12 and the second fixed sensor element 13 can each form a measuring electrode together with the printed circuit board 15, while the third movable sensor element 14 forms a counter-electrode, or vice versa.

In addition, the movable sensor element 14 can be encapsulated by a foam material (not shown in detail), at least in regions, and can be designed as an integrated component with the fixed sensor elements 12, 13 and the printed circuit board 15. In the assembled state, the electronic actuating module 5 can be formed as a pre-assembled unit. The actuating module 5 can be mounted as a pre-assembled unit in a decorative element 4 and/or in a handle module. The sensor elements 12 to 14 can also be designed as separate integrated components or as a common integrated component and form at least one further pre-assembled subunit.

The movable sensor element 14 and the fixed sensor elements 12, 13 are arranged relative to one another in such a way that, when an actuating force 30, for example a manual actuating force, acts on the actuating module 5, in particular on the actuation sensor 10, the movable sensor element 14 can be displaced relative to at least one of the fixed sensor elements 12, 13 depending on the transmission.

For example, an actuating movement resulting from the actuating force 30, in particular an actuation stroke 20 resulting from the actuating force 30, causes the movable sensor element 14 to be displaced, at least in regions, in the direction of the fixed sensor elements 12, 13.

For example, the movable sensor element 14 can be arranged in a starting position P1 at a predetermined distance D1, D2 from the fixed sensor elements 12, 13. The movable sensor element 14 can be designed in such a way that it is arranged at different distances D1, D2 from the corresponding fixed sensor element 12, 13. In other words, in a starting position P1, the movable sensor element 14 has a different distance D1, D2 from the corresponding the fixed sensor element 12, 13. For example, the movable sensor element 14 can be designed and/or oriented in such a way that it is arranged further away from, or closer to, one of the fixed sensor elements 12, 13 than to the other fixed sensor element 12, 13. The movable sensor element 14 can be designed and/or oriented in such a way that it is closer to one of the fixed sensor elements 12, 13 than to the other fixed sensor element 12, 13. For example, the movable sensor element 14 can be arranged at an incline to a surface side of each of the fixed sensor elements 12, 13.

The two fixed sensor elements 12, 13 are parallel to one another. In particular, the fixed sensor elements 12, 13 are arranged in one plane. Alternatively, the fixed sensor elements 12, 13 can be located in different planes.

For example, a distance D1 between the movable sensor element 14 and the first fixed sensor element 12 is smaller or larger than a distance D2 between the movable sensor element 14 and the second fixed sensor element 13.

Alternatively, the movable sensor element 14 can be arranged in parallel with and opposite the fixed sensor elements 12, 13.

The movable sensor element 14 can be moved from the starting position P1 to an intermediate position P2 which is moved relative to the fixed sensor elements 12, 13.

An end stop 16 is arranged between the fixed sensor elements 12, 13. The end stop 16 can be attached to the printed circuit board 15. The end stop 16 is provided to support the movable sensor element 14 in its end position P3. In the end position P3, the movable sensor element 14 comes to abut the end stop 16. The end stop 16 can be made of a non-conductive material. For example, the end stop 16 is made of a plastics material.

The movable sensor element 14 is reversibly flexible or elastic.

The actuating module 5 comprises a housing 40. The actuation sensor 10 and the electronic unit 11 are accommodated in the housing 40 and are protected from external influences. An upper side 41 of the housing 40 is flexible or elastic at least in some regions so that an actuating force 30 acting on the actuating module 5 deforms the upper side 41 of the housing, at least in some regions. The movable sensor element 14 is arranged below the upper side 41 of the housing 40. The movable sensor element 14 can be arranged at a distance from the upper side 41 of the housing 40. The movable sensor element 14 can be connected to, or at least be in contact with, the upper side 41 of the housing in some regions, for example as shown in FIG. 4.

The electronic unit 11 comprises at least one evaluation unit 17. The electronic unit 11 can be equipped with a control unit 18, for example a so-called ECU (electronic control unit). The evaluation unit 17 can be coupled with the control unit 18.

The first fixed sensor element 12 has a first sensitivity region 121 for capacitance changes. The second fixed sensor element 13 has a second sensitivity region 131 for capacitance changes.

When an actuating force 30 acts on the actuation sensor 10, the movable sensor element 14 can be displaced, at least in some regions, in such a way that an actuation stroke 20 resulting from the actuating force 30 can be detected in the first sensitivity region 121 or in the second sensitivity region 131 or simultaneously in the first and second sensitivity regions 121, 131 and can be compared with a predetermined threshold value.

A force is applied to the actuation sensor 10, for example a pressure force on the upper side 41 of the housing of the actuating module 5. If an actuation stroke 20 resulting from the force exceeds a predefined threshold value of a few millimeters, for example, this is identified as a request to open and/or unlock a lock, for example.

The evaluation unit 17 is set up to use recorded measured values of a capacitance change in the first sensitivity region 121 and/or in the second sensitivity region 131 to decide which of these measured values will be used for further evaluation in order to identify an actuation request, in particular a triggering request.

When an actuation stroke 20 is detected in the first sensitivity region 121 or in the second sensitivity region 131, the evaluation unit 17 is set up to compare this stroke with a predetermined first threshold value or a predetermined second threshold value. Here, for example, the actuating module 5, in particular the upper side 41 of the housing, is subjected to an actuating force 30 substantially off-center, for example in an edge region.

When an actuation stroke 20 is detected in the first sensitivity region 121 and in the second sensitivity region 131, the evaluation unit 17 is also set up to compare this stroke with a predefined third threshold value. For example, the actuating module 5, in particular the upper side 41 of the housing, is subjected to an actuating force 30 substantially in the center.

The movable sensor element 14 is, for example, a metal sheet and/or spring sheet.

In order to provide a transmission ratio, the movable sensor element 14 can be designed as a lever, in particular as a one-sided lever or as a two-sided lever. The movable sensor element 14, which is designed as a lever, can be pivotable or bendable around a first end point 141.

In particular, the movable sensor element 14 can be arranged at a predetermined angle 142 to the fixed sensor elements 12, 13. For example, the movable sensor element 14 is arranged and held at an angle 142 to the fixed sensor elements 12, 13 such that a transmission ratio of an actuating movement of the upper side 41 of the housing to a sensor movement or sensor displacement of the movable sensor element 14 can be provided or set. This allows for a compact design of the actuating module 5, and small actuation strokes 20. In addition, the actuating forces 30 can be set; in particular, threshold values can be specified.

For example, the movable sensor element 14 can, on the one hand, be flexibly or pivotally hinged to the printed circuit board 15. On the other hand, a free lever end, in particular a second end point 143, of the movable sensor element 14 is arranged with a predetermined incline at a distance from the fixed sensor elements 12, 13, and overlapping them. The predetermined incline can correspond to the predetermined angle 142 of the movable sensor element 14 to the fixed sensor elements 12, 13.

In the illustrated embodiment, the movable sensor element 14 comprises a first lever portion 144 which is arranged with a first incline at a distance from the first fixed sensor element 12. The movable sensor element 14 comprises a second lever portion 145 which is arranged with a second incline at a distance from the second fixed sensor element 13. The lever portions 144, 145 can differ in terms of their inclines. For example, for an improved transmission ratio, the movable sensor element 14 can be arranged in the region of the first lever portion 144 at a smaller distance D1 from the sensitivity region 121 of the first fixed sensor element 12. For example, for an improved transmission ratio, the movable sensor element 14 can be arranged in the region of the second lever portion 145 at a greater distance D2 from the sensitivity region 131 of the second fixed sensor element 13. For example, a transmission ratio can be set such that a short actuating path is converted to a long sensor path. Reliable sensor detection is thereby made possible, and sensor sensitivity is increased in a simple manner.

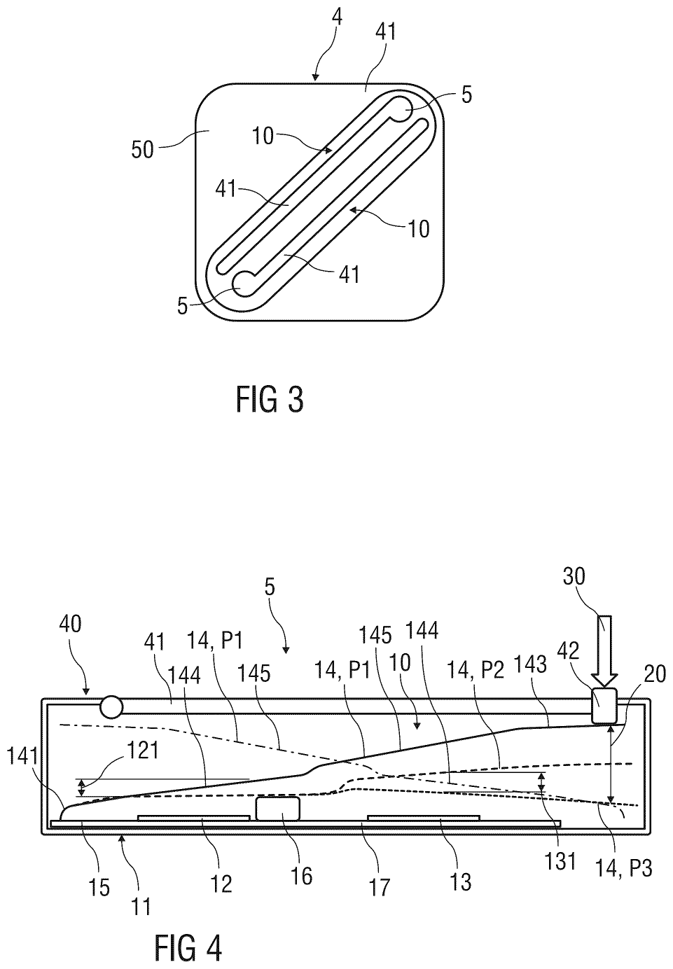

FIG. 3 shows a schematic top view of a decorative element 4 with two adjacent actuating modules 5. The decorative element 4 comprises two identical actuating modules 5, which are arranged mirror-inverted to each other below a surface side 50. The upper sides 41 of the housing of the actuating modules 5 can be formed in one piece with, or connected to, the surface side 50 of the decorative element 4. An actuating force 30 acting on the surface side 50 of the decorative element 4 causes an elastic deformation of a region of the surface side 50, wherein the deformation of the decorative element 4 causes a deformation of the upper side 41 of the housing of the corresponding actuating module 5 or directly causes the displacement of the movable sensor element 14.

The decorative element 4 thus comprises two actuating modules 5, each with two fixed sensor elements 12, 13 and a movable sensor element 14, which can be used to detect or record where, i.e. at which point, pressure is applied on the decorative element 4. Different threshold values can be stored for different actuation points on the actuating module 5. For example, a threshold value for detecting an actuation in a central or middle region of the decorative element 4 and/or of the actuating module 5 is lower than a threshold value for detecting an actuation in an off-center, for example edge, region of the decorative element 4 and/or of the actuating module 5. A triggering path can be set, for example modified, depending on the point of contact on the decorative element 4 and/or on the actuating module 5.

If at least two actuating modules 5 are used, both actuating modules 5 can be coupled to a common evaluation unit 17.

When an actuating force 30 acts on the decorative element 4, the movable sensor element 14 of a first actuating module 5 and the movable sensor element 14 of a second actuating module 5 can each be displaced at least in some regions relative to the fixed sensor elements 12, 13 assigned thereto. The movable sensor elements 14 are adjacent or next to each other, for example. Because the actuating modules 5 are arranged mirror-inverted to each other, the sensor elements 12 to 14 are also arranged mirror-inverted to each other. The inclines of the respective movable sensor elements 14 are oriented mirror-inverted to each other (as shown schematically in FIG. 4).

In other words, the first lever portion 144 of a first movable sensor element 14 is adjacent to, for example transversely opposite, the second lever portion 145 of a second movable sensor element 14. The second lever portion 145 of the first movable sensor element 14 is adjacent to the first lever portion 144 of the second movable sensor element 14.

If a user actuates the decorative element 4 substantially off-center or at the edge, an actuation stroke 20 resulting from the actuating force 30 causes a simultaneous displacement of the first movable sensor element 14 and the second movable sensor element 14. In each case, the first lever portion 144 of one of the two movable sensor elements 14 and the second lever portion 145 of the other of the two movable sensor elements 14 is displaced. The evaluation unit 17 can determine a location where the force was applied by comparing values recorded at each lever portion 144, 145. The values are different due to the distance D1, D2 between the corresponding lever portion 144, 145 and the associated fixed sensor elements 12, 13. The evaluation unit 17 can then compare the recorded values with the predefined threshold values assigned thereto.

Given actuation in a central region of the decorative element 4, the evaluation unit 17 can be used to determine substantially the same values at both movable sensor elements 14. This allows the evaluation unit 17 to determine that the decorative element 4 has been actuated substantially in the center. The evaluation unit 17 can then compare the recorded values with the predefined threshold values assigned thereto.

FIG. 4 is a schematic side view of a further embodiment of an actuating module 5 according to the invention with an actuation sensor 10 and an electronic unit 11.

The actuating module 5 comprises at least one actuation sensor 10 for executing a switching function and an electronic evaluation unit 17 connected to the actuation sensor 10, wherein the actuation sensor 10 has at least two fixed sensor elements 12, 13 and a sensor element 14 which is movable relative to the fixed sensor elements 12, 13 and which is arranged opposite the fixed sensor elements 12, 13. The actuation sensor 10 comprises a first fixed sensor element 12 with a first sensitivity region 121 and a second fixed sensor element 13 with a second sensitivity region 131, wherein, when an actuating force 30 acts on the actuation sensor 10, the movable sensor element 14 can be displaced, at least in some regions, in such a way that an actuation stroke 20 resulting from the actuating force 30 can be detected in the first sensitivity region 121 and/or in the second sensitivity region 131 and can be compared with at least one predetermined threshold value.

The evaluation unit 17 can be set up to detect an actuation stroke 20 on the basis of a displacement of the movable sensor element 14 into the first sensitivity region 121 and/or into the second sensitivity region 131 and to compare this with a predetermined threshold value in order to generate a trigger signal for a switching function if the threshold value is exceeded. The sensitivity regions 121, 131 can be the same or different. Depending on how the sensitivity regions 121, 131 are set, the actuation sensor 10 can react comparatively more sensitively or less sensitively to a change in capacitance. When the movable sensor element 14 is displaced, a distance D1, D2 between the movable sensor element 14, for example a trigger element, and at least one of the fixed sensor elements 12, 13 is reduced or increased so that a measuring field present therebetween changes.

The movable sensor element 14 can be designed as a flexible trigger element. The movable sensor element 14 is designed to reset automatically. The movable sensor element 14 is, for example, a spring element and/or is designed as a return spring.

In the embodiment shown, the upper side 41 of the housing 40 of the actuating module 5 that is elastically deformable, at least in regions, is provided with an actuating element 42. The actuating element 42 acts on the movable sensor element 14 at an engagement point, for example at the second end point 143 of the movable sensor element 14, in order to actuate it. The actuating force 30 preferably acts perpendicularly to the lever, i.e. to the movable sensor element 14.

For example, the actuating element 42 can be an actuating plunger or actuating pin. When the actuating module 5 is actuated, in particular the upper side 41 of the housing, the actuating element 42 can come into engagement with the movable sensor element 14 in the region of a free end point 143 thereof and move the movable sensor element 14 toward the fixed sensor elements 12, 13.

The actuating element 42 can be designed as a pressure transmission element or can comprise such an element, which extends in the direction of the actuation sensor 10. For example, the actuating element 42 comprises a pressure pin, e.g. a bolt or pin, directed in the direction of the actuation sensor 10, in particular in the direction of the movable sensor element 14, which pin can be moved in the pressure direction that corresponds to the actuation direction in order to actuate the movable sensor element 14. As a result, the distance D1, D2 between the movable sensor element 14 and the fixed sensor elements 12, 13 is reduced so that a measuring field arranged therebetween changes. For this purpose, the movable sensor element 14 is designed, for example, as a lever-shaped spring plate or a lever-shaped spring sheet.

### LIST OF REFERENCE SIGNS

1 Vehicle
2 Door
3 Tailgate
4 Decorative element
5 Actuating module
6 Handle
10 Actuation sensor
11 Electronic unit
12 Fixed sensor element
121 Sensitivity region
13 Fixed sensor element
131 Sensitivity region
14 Movable sensor element
141 End point
142 Angle
143 End point
144 Lever portion
145 Lever portion
15 Printed circuit board
16 End stop
17 Evaluation unit
18 Control unit
20 Actuation stroke
30 Actuating force
40 Housing
41 Upper side of housing
42 Actuating element
50 Surface side
D1, D2 Distance
P1 Starting position
P2 Intermediate position
P3 End position
x Longitudinal axis
y Transverse axis
z Vertical axis

What is claimed is:

1. An actuating module for a vehicle, comprising:
an actuation sensor for executing a switching function and
an electronic evaluation unit connected to the actuation sensor,
wherein the actuation sensor comprises at least
a first fixed sensor element with a first sensitivity region,
a second fixed sensor element with a second sensitivity region and
a sensor element which is movable relative to the fixed sensor elements and is arranged opposite the fixed sensor elements,
wherein the movable sensor element overlaps the fixed sensor elements, wherein, in a starting position, the movable sensor element is arranged at a different distance from the corresponding fixed sensor element and can be displaced, at least in some regions, relative to the fixed sensor elements when an actuating force acts on the actuation sensor.

2. The actuating module according to claim 1, wherein the movable sensor element is designed and/or oriented so as to be closer to one of the fixed sensor elements than to the other fixed sensor element, wherein both fixed sensor elements lie on one plane.

3. The actuating module according to claim 1, wherein the movable sensor element can be displaced, at least in some regions, when an actuating force acts on the actuation sensor and an actuation stroke resulting from the actuating force can be detected in the first sensitivity region and/or in the second sensitivity region.

4. The actuating module according to claim 1, wherein, when an actuation stroke is detected in the first sensitivity region or in the second sensitivity region, the evaluation unit is set up to compare said stroke with a predetermined first threshold value or a predetermined second threshold value.

5. The actuating module according to claim 4, wherein, when an actuation stroke is detected in the first sensitivity region and in the second sensitivity region, the evaluation unit is set up to compare said stroke with a predetermined third threshold value.

6. The actuating module according to claim 4, wherein the threshold values and/or the sensitivity regions are set or settable so as to be different.

7. The actuating module according to claim 4, wherein, when the movable sensor element is displaced, a capacitance change can be detected in the relevant sensitivity region.

8. The actuating module according to claim 4, wherein the movable sensor element is designed as a lever and is arranged at a predetermined angle to the fixed sensor elements.

9. The actuating module according to claim 4, wherein the movable sensor element comprises at least a first lever portion arranged with a first incline at a distance from the first fixed sensor element, and a second lever portion arranged with a second incline at a distance from the second fixed sensor element.

10. A decorative element for the vehicle, comprising the at least one actuating module according to claim 4, wherein a surface side of the decorative element deforms elastically in some regions when an actuating force is applied and brings about the displacement of the movable sensor element in some regions.

11. The decorative element according to claim 10, wherein two identical actuating modules are provided, which are arranged mirror-inverted to each other below the surface side of the decorative element.

12. The decorative element according to claim 11, wherein, when the actuating force acts on the decorative element, the movable sensor element of the first actuating module and the movable sensor element of the second actuating module can each be displaced, at least in some regions, relative to the fixed sensor elements assigned thereto.
